(19) United States
(12) Patent Application Publication
(10) Pub. No.: US 2015/0255653 A1
(43) Pub. Date: Sep. 10, 2015

(54) SOLAR CELL MODULE WITH A NANOFILLED ENCAPSULANT LAYER

(71) Applicant: E.I. DU PONT DE NEMOURS AND COMPANY, Wilmington, DE (US)

(72) Inventors: Sam Louis Samuels, Landenberg, PA (US); Gordon Mark Cohen, Wynnewood, PA (US); Mark David Wetzel, Newark, DE (US)

(21) Appl. No.: 14/430,579

(22) PCT Filed: Oct. 11, 2013
(86) PCT No.: PCT/US13/64425

§ 371 Date: Mar. 24, 2015

Related U.S. Application Data
(63) Continuation of application No. PCT/US2013/064207, filed on Oct. 10, 2013.
(60) Provisional application No. 61/713,037, filed on Oct. 12, 2012.

(51) Int. Cl. H01L 31/048; H01L 31/18

(52) U.S. Cl. CPC H01L 31/0481; H01L 31/18

(57) ABSTRACT

A solar cell module comprising a solar cell layer and a sheet comprising at least one layer of a nanofilled ionomer composition, wherein the nanofilled ionomer composition comprises (1) an ionomer that is derived from a precursor α-olefin carboxylic acid copolymer wherein (a) the precursor α-olefin carboxylic acid copolymer comprises (i) copolymerized units of an α-olefin and (ii) about 20 to about 25 weight % of copolymerized units of an α,β-ethylenically unsaturated carboxylic acid; and (b) at least a portion of the total content of the carboxylic acid groups present in the precursor α-olefin carboxylic acid copolymer have been neutralized to form metal salts of the carboxylic acid groups; and (2) one or more nanofillers.

This application claims priority from U.S. Provisional Patent Application Ser. No. 61/713,037, filed Oct. 12, 2012 and PCT Application Serial Number PCT/US13/64207, filed Oct. 10, 2013.

### FIELD OF THE INVENTION

The present invention is directed to solar cell modules having encapsulant sheet layers that exhibit a low degree of creep or heat deformation. In particular, the present invention relates to solar cell modules comprising an encapsulant sheet. The encapsulant sheet comprises at least one layer of a composition comprising an ionomer and nanofiller.

### BACKGROUND OF THE INVENTION

Several patents, patent applications and publications are cited in this description in order to more fully describe the state of the art to which this invention pertains. The entire disclosure of each of these patents, patent applications and publications is incorporated by reference herein.

Because they provide a sustainable energy resource, the use of solar cells is rapidly expanding. Solar cells can typically be categorized into two types based on the light absorbing material used, i.e., bulk or wafer-based solar cells and thin film solar cells.

Monocrystalline silicon (c-Si), poly- or multi-crystalline silicon (poly-Si or mc-Si) and ribbon silicon are the materials used most commonly in forming traditional wafer-based solar cells. Solar cell modules derived from wafer-based solar cells often comprise a series of self-supporting wafers (or cells) that are soldered together. The wafers generally have a thickness of between about 180 and about 240 μm. Such a panel of solar cells is called a solar cell layer and it may further comprise electrical wirings such as cross ribbons connecting the individual cell units and bus bars having one end connected to the cells and the other exiting the module. The solar cell layer is then further laminated to encapsulant layer(s) and protective layer(s) to form a weather resistant module that may be used for up to 25 years, up to 30 years, or longer. In general, a solar cell module derived from wafer-based solar cell(s) comprises, in order of position from the front light-receiving side to the back non-light-receiving side: (1) an incident layer, (2) a front encapsulant layer, (3) a solar cell layer, (4) a back encapsulant layer, and (5) a backing layer.

Alternatively, thin film solar cells are commonly formed from materials that include amorphous silicon (a-Si), microcrystalline silicon (μc-Si), cadmium telluride (CdTe), copper indium selenide (CuInSe₂ or CIS), copper indium/gallium diselenide (CuInₓGa₍₁₋ₓ₎Se₂ or CIGS), light absorbing dyes, and organic semiconductors. By way of example, thin film solar cells are disclosed in U.S. Pat. Nos. 5,507,881; 5,512,107; 5,948,176; 5,994,163; 6,040,521; 6,137,048; and 6,258,620 and U.S. Patent Publications 20070298590; 20070281090; 20070240759; 20070232057; 20070238285; 20070227578; 20070209699; and 20070079866. Thin film solar cells with a typical thickness of less than 2 μm are produced by depositing the semiconductor layers onto a superstrate or substrate formed of glass or a flexible film. During manufacture, it is common to include a laser scribing sequence that enables the adjacent cells to be directly interconnected in series, with no need for further solder connections between cells. As with wafer cells, the solar cell layer may further comprise electrical wirings such as cross ribbons and bus bars. Similarly, the thin film solar cells are further laminated to other encapsulant and protective layers to produce a weather resistant and environmentally robust module.

Depending on the sequence in which the multi-layer deposition is carried out, the thin film solar cells may be deposited on a superstrate that ultimately serves as the incident layer in the final module, or the cells may be deposited on a substrate that ends up serving as the backing layer in the final module. Therefore, a solar cell module derived from thin film solar cells may have one of two types of construction. The first type includes, in order of position from the front light-receiving side to the back non-light-receiving side, (1) a solar cell layer comprising a superstrate and a layer of thin film solar cell(s) deposited thereon at the non-light-receiving side, (2) a (back) encapsulant layer, and (3) a backing layer. The second type includes, in order of position from the front light-receiving side to the back non-light-receiving side, (1) an incident layer, (2) a (front) encapsulant layer, (3) a solar cell layer comprising a layer of thin film solar cell(s) deposited on a substrate at the light-receiving side thereof, and, optionally, (4) an additional (back) encapsulant layer and (5) a backing layer.

The encapsulant layers used in solar cell modules are designed to encapsulate and protect the fragile solar cells. Suitable polymer materials for solar cell encapsulant layers typically possess a combination of characteristics such as high impact resistance, high penetration resistance, good ultraviolet (UV) light resistance, good long term thermal stability, adequate adhesion strength to glass and other rigid polymeric sheets, high moisture resistance, and good long term weatherability. In addition, the front encapsulant layers should be transparent enough to allow sunlight to effectively reach the solar cells, so that the solar cells generate the highest power output possible. Thus, it is very desirable that the polymer materials utilized in the front encapsulant layers exhibit a combination of low haze and high clarity.

Traditional encapsulant materials (e.g., EVA, silicone) are crosslinked during lamination and do not subsequently flow or deform when exposed to high temperature environments. However, crosslinking is a time consuming process that can limit productivity. Thermoplastic materials, on the other hand, are not crosslinked and must flow at lamination temperatures (typically greater than 130° C.), which has led to a concern that flow could also occur in a solar cell module under high temperature operating conditions. It is known, for example, that modules can reach peak temperatures greater than 100° C. in extreme environments.

The possibility of deformation, flow or creep of thermoplastic encapsulants under high-temperature operating conditions has led to a concern about potential failures in the performance or safety of solar cell modules. Although full module tests would be required to assure safety and module performance after exposure to such conditions, measurement of the amount of movement (creep) of a test glass laminate after exposing the glass/encapsulant/glass laminate to an elevated temperature for a specified amount of time can provide insights into relative creep performance of various materials in similar configurations, e.g. frameless glass-glass modules.

It is common in the plastics industry to blend various additives with a matrix polymer for the purpose of improving one or more polymer physical properties. In recent years, highly effective nanoparticle fillers have been developed and used as additives in polymer matrices in place of conventional mineral fillers. For example, U.S. Pat. No. 7,270,862 discloses combinations of nanofillers and polyolefins that impart improved barrier properties to polyamide compositions.

Ionomers are thermoplastic polymers that possess many desirable characteristics for use in solar cell encapsulant layers. Ionomers are produced by partially or fully replacing the hydrogen atoms of the acid moieties of precursor (also known as “parent”) acid copolymers with ionic moieties. This is generally accomplished by neutralizing the parent acid copolymers, for example copolymers comprising copolymerized units of α-olefins and α,β-ethylenically unsaturated carboxylic acids. Neutralization of the carboxylic acid groups present in such parent or precursor copolymers is generally effected by reaction of the copolymer with a base, e.g., sodium hydroxide or magnesium hydroxide, whereby the hydrogen atoms of the carboxylic acids are replaced by the cations of the base. The ionomers thus formed are ionic, fully or partially neutralized polymers that comprise carboxylate groups having cations derived from reaction of the carboxylic acid with the base. Ionomers are well known in the art and include polymers wherein the cations of the carboxylate groups of the ionomer are metal cations, including alkali metal cations, alkaline earth cations and transition metal cations. Commercially available ionomers include those having sodium, lithium, potassium, magnesium and zinc cations.

The use of ionomer compositions as interlayers in laminated safety glass is known in the art. See, e.g., U.S. Pat. Nos. 3,344,014; 3,762,988; 4,663,228; 4,668,574; 4,799,346; 5,759,698; 5,763,062; 5,895,721; 6,150,028; and 6,432,522, U.S. Patent Publications 20020155302; 20020155302; 20060182983; 20070092706; 20070122633; 20070289693, and PCT Patent Publications WO9958334; WO2006057771 and WO2007149082.

In recent years, ionomer compositions have been developed as solar cell encapsulant materials. See, e.g., U.S. Pat. Nos. 5,476,553; 5,478,402; 5,733,382; 5,741,370; 5,762,720; 5,986,203; 6,114,046; 6,187,448; 6,353,042; 6,320,116; and 6,660,930, and U.S. Patent Publications 20030000568, 20050279401 and 20100108125. For example, U.S. Pat. No. 5,476,553 discloses the use, among others, of sodium ionomers such as Surlyn® 1601 resin as an encapsulant material. U.S. Pat. No. 6,114,046 discloses a multi-layer metallocene polyolefin/ionomer laminate structure that can be used as an encapsulant. Various types of ionomers, including sodium and zinc ionomers, are described.

It is desirable to produce ionomer compositions with minimal creep for use in solar cell modules capable of more robust performance, such as in high-temperature operating conditions.

### SUMMARY OF THE INVENTION

The invention provides solar cell module comprising a solar cell layer and a sheet comprising at least one layer of a nanofilled ionomer composition, wherein (a) the solar cell layer comprises a single solar cell or a plurality of electrically interconnected solar cells; (b) the solar cell layer has a light-receiving side and a non-light-receiving side; and (c) the nanofilled ionomer composition comprises
(1) an ionomer that is an ionic, neutralized derivative of a precursor α-olefin carboxylic acid copolymer, wherein about 10% to about 35% of the total content of the carboxylic acid groups present in the precursor α-olefin carboxylic acid copolymer is neutralized to form salts containing alkali metal cations, alkaline earth metal cations, transition metal cations, or combinations of two or more of these metal cations, and wherein the precursor α-olefin carboxylic acid copolymer comprises (i) copolymerized units of an α-olefin having 2 to 10 carbons and (ii) about 15 to about 25 weight %, based on the total weight of the precursor α-olefin carboxylic acid copolymer, of copolymerized units of an α,β-ethylenically unsaturated carboxylic acid having 3 to 8 carbons, wherein the ionomer has a melt flow rate (MFR) of about 0.1 g/10 min to about 60 g/10 min,
(2) one or more nanofillers; and optionally
(3) a second ionomer comprising a parent acid copolymer that comprises copolymerized units of ethylene and about 18 to about 30 weight % of copolymerized units of acrylic acid or methacrylic acid, based on the total weight of the parent acid copolymer, the acid copolymer having a melt flow rate (MFR) from about 200 to about 1000 g/10 min., wherein about 50% to about 70% of the carboxylic acid groups of the copolymer, based on the total carboxylic acid content of the parent acid copolymer as calculated for the non-neutralized parent acid copolymer, are neutralized to carboxylic acid salts comprising sodium cations, potassium cations or a combination thereof; and the second ionomer has a MFR from about 1 to about 20 g/10 min. wherein MFR is measured according to ASTM D1238 at 190° C. with a 2.16 kg load.

In one embodiment, the solar cell module comprises a front encapsulant layer laminated to the light-receiving side of the solar cell layer and a back encapsulant layer laminated to the non-light-receiving side of the solar cell layer, wherein at least one of the front and back encapsulant layers comprises the sheet comprising the nanofilled ionomer composition, preferably wherein a layer comprising the nanofilled ionomer composition is directly laminated to the solar cell layer.

In another embodiment, the solar cell module comprises, in order of position, (i) an incident layer, (ii) a front encapsulant layer comprising the sheet comprising the nanofilled ionomer composition, and (iii) the solar cell layer, wherein the solar cell layer further comprises a substrate upon which the thin film solar cells are deposited and the substrate is positioned such that the substrate is an outermost surface of the module and is positioned on the non-light-receiving side of the solar cell layer.

In another embodiment, the solar cell module comprises in order of position, (i) the solar cell layer, (ii) a back encapsulant layer comprising the sheet comprising the nanofilled ionomer composition, and (iii) a backing layer, wherein the solar cell layer further comprises a superstrate upon which the thin film solar cells are deposited and the superstrate is positioned such that the superstrate is an outermost surface of the module on the light-receiving side of the solar cell layer.

The invention further provides a process for preparing the solar cell module described above, comprising: (i) providing an assembly comprising the solar cell layer and a sheet having at least one layer of a nanofilled ionomer composition described above; and (ii) laminating the assembly to form the solar cell module, wherein the laminating step is conducted by subjecting the assembly to heat, optionally further comprising subjecting the assembly to vacuum or pressure.

### DETAILED DESCRIPTION OF THE INVENTION

Unless otherwise defined, all technical and scientific terms used herein have the same meaning as commonly understood by one of ordinary skill in the art to which this invention belongs. In case of conflict, the specification, including definitions, will control.

Although methods and materials similar or equivalent to those described herein can be used in the practice or testing of the invention, suitable methods and materials are described herein.

Unless stated otherwise, all percentages, parts, ratios, etc., are by weight. When an amount, concentration, or other value or parameter is given as either a range, preferred range or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

When the term “about” is used in describing a value or an end-point of a range, the disclosure should be understood to include the specific value or end-point referred to.

As used herein, the terms “comprises,” “comprising,” “includes,” “including,” “containing,” “characterized by,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or.

The transitional phrase “consisting essentially of” limits the scope of a claim to the specified materials or steps and those that do not materially affect the basic and novel characteristic(s) of the claimed invention. Where applicants have defined an invention or a portion thereof with an open-ended term such as “comprising,” it should be understood that unless otherwise stated the description should be interpreted to also describe such an invention using the term “consisting essentially of”.

Use of “a” or “an” are employed to describe elements and components of the invention. This is merely for convenience and to give a general sense of the invention. This description should be read to include one or at least one and the singular also includes the plural unless it is obvious that it is meant otherwise. The term “or”, as used herein, is inclusive; that is, the phrase “A or B” means “A, B, or both A and B”. Exclusive “or” is designated herein by terms such as “either A or B” and “one of A or B”, for example.

In describing certain polymers it should be understood that sometimes applicants are referring to the polymers by the monomers used to produce them or the amounts of the monomers used to produce the polymers. While such a description may not include the specific nomenclature used to describe the final polymer or may not contain product-by-process terminology, any such reference to monomers and amounts should be interpreted to mean that the polymer comprises those monomers (i.e. copolymerized units of those monomers) or that amount of the monomers, and the corresponding polymers and compositions thereof. In describing and/or claiming this invention, the term “copolymer” is used to refer to polymers formed by copolymerization of two or more monomers. Such copolymers include dipolymers, terpolymers or higher order copolymers.

The term “acid copolymer” as used herein refers to a polymer comprising copolymerized units of an α-olefin, an α,β-ethylenically unsaturated carboxylic acid, and optionally, other suitable comonomer(s) such as an α,β-ethylenically unsaturated carboxylic acid ester.

The term “ionomer” as used herein refers to a polymer that comprises ionic groups that are metal ion carboxylates, for example, alkali metal carboxylates, alkaline earth carboxylates, transition metal carboxylates and/or mixtures of such carboxylates. Such polymers are generally produced by partially or fully neutralizing the carboxylic acid groups of a precursor or “parent” polymer that is an acid copolymer, as defined herein, for example by reaction with a base. An example of an alkali metal ionomer as used herein is a sodium ionomer (or sodium neutralized ionomer), for example a copolymer of ethylene and methacrylic acid wherein all or a portion of the carboxylic acid groups of the copolymerized methacrylic acid units are in the form of sodium carboxylates.

As used herein, the term “nanofiller” refers to inorganic materials, including without limitation solid allotropes and oxides of carbon, having a particle size of about 0.9 to about 200 nm in at least one dimension. The related terms “nanofilled” and “nanocomposite” refer to a composition that contains nanofiller dispersed in a polymer matrix. In particular, a nanofilled ionomer composition contains a nanofiller dispersed in a polymer matrix comprising an ionomer as defined above.

The term “dispersed”, as used herein with respect to nanofiller in a polymer matrix, refers to a state in which the nanofiller particles are sufficiently small in size and sufficiently surrounded by the polymer matrix so that the optical clarity of the nanocomposite is not significantly compromised. In particular, the nanofiller is dispersed when the haze of the nanocomposite is less than 5% and the difference in Transmitted Solar Energy (τₛₑ) between the polymer matrix and the nanocomposite is less than 0.5%.

The invention provides a solar cell module comprising a) at least one layer that is a sheet comprising at least one layer of a nanofilled ionomer composition and b) a solar cell layer comprising one or a plurality of solar cells. The sheet functions as an encapsulant layer in the solar cell module. That is, the solar cell modules are characterized by having an encapsulant layer having at least one layer of a nanofilled ionomer composition.

The addition of certain nanoparticles to thermoplastic polymers has now been shown to significantly increase low shear viscosity and to reduce flow. It has been found that the addition of these nanoparticles to ionomers provides thermoplastic encapsulants that are “creep resistant” while maintaining transparency. Laminates comprising ionomeric interlayers that were not modified by inclusion of nanofillers deformed significantly in creep measurement tests above 100° C., while laminates comprising nanofilled ionomer compositions as interlayers surprisingly showed little or no deformation after extended exposure to temperatures of 105° C. or 115° C. Also, in general, nanoclay particles are highly polar and prefer to associate with each other rather than a polymer that is of lower polarity, resulting in a poor dispersion. Surprisingly, the separated nanofiller particles that are dispersed in the ionomer as described herein do not re-agglomerate under melt processing conditions.

The nanofilled ionomer compositions used herein contain ionomers that are ionic, neutralized derivatives of precursor acid copolymers. Examples of suitable ionomers are described in U.S. Pat. No. 7,763,360 and U.S. Patent Application Publication 2010/0112253, for example. Briefly, however, suitable precursor acid copolymers comprise copolymerized units of an α-olefin having 2 to 10 carbons and about 15 to about 25 weight % of copolymerized units of an α,β-ethylenically unsaturated carboxylic acid having 3 to 8 carbons, and 0 to about 40 weight % of other comonomers. The weight percentages are based on the total weight of the precursor acid copolymer. In addition, the amount of copolymerized α-olefin is complementary to the amount of copolymerized α,β-ethylenically unsaturated carboxylic acid and of other comonomer(s), if present, so that the sum of the weight percentages of the comonomers in the precursor acid copolymer is 100%.

Suitable α-olefin comonomers include, but are not limited to, ethylene, propylene, 1-butene, 1-pentene, 1-hexene, 1-heptene, 3 methyl-1-butene, 4-methyl-1-pentene, and the like and mixtures of two or more thereof. Preferably, the α-olefin is ethylene.

Suitable α,β-ethylenically unsaturated carboxylic acid comonomers include, but are not limited to, acrylic acids, methacrylic acids, itaconic acids, maleic acids, maleic anhydrides, fumaric acids, monomethyl maleic acids, and mixtures of two or more thereof. Preferably, the α,β-ethylenically unsaturated carboxylic acid is selected from acrylic acids, methacrylic acids, and mixtures thereof.

The precursor α-olefin carboxylic acid copolymer may comprise about 18 to about 25 weight %, preferably about 18 to about 23 weight %, such as about 18 to about 20 weight % or about 21 to about 23 weight %, of copolymerized units of the α,β-ethylenically unsaturated carboxylic acid and the precursor α-olefin carboxylic acid copolymer may have a melt flow rate of about 100 g/10 min or less, preferably about 30 g/10 min or less. Preferably, the α-olefin is ethylene. Preferably, the carboxylic acid is acrylic acid or methacrylic acid.

The precursor acid copolymers may further comprise copolymerized units of other comonomer(s), such as unsaturated carboxylic acids having 2 to 10, or preferably 3 to 8 carbons, or derivatives thereof. Suitable acid derivatives include acid anhydrides, amides, and esters. Esters are preferred. Specific examples of preferred esters of unsaturated carboxylic acids include, but are not limited to, those described in U.S. Patent Application Publication 2010/0112253. Examples of more preferred comonomers include, but are not limited to, alkyl (meth)acrylates such as methyl acrylate, methyl methacrylate, butyl acrylate, and butyl methacrylate; other (meth)acrylate esters, such as glycidyl methacrylates; vinyl acetates, and mixtures of two or more thereof. Alkyl acrylates are most preferred. The precursor acid copolymers may comprise 0 to about 40 weight % of other comonomers; such as about 5 to about 25 weight %. The presence of other comonomers is optional, however, and in some solar cell modules it is preferable that the precursor acid not include any other comonomer(s).

The precursor acid copolymers may be polymerized as disclosed in U.S. Pat. Nos. 3,404,134; 5,028,674; 6,500,888; 6,518,365; 7,763,360 and U.S. Patent Application Publication 2010/0112253. Preferably, the precursor acid copolymers are polymerized under process conditions such that short chain and long chain branching is maximized. Such processes are disclosed in, e.g., P. Ehrlich and G. A. Mortimer, “Fundamentals of Free-Radical Polymerization of Ethylene”, Adv. Polymer Sci., Vol. 7, p. 386-448 (1970) and J. C. Woodley and P. Ehrlich, “The Free Radical, High Pressure Polymerization of Ethylene II. The Evidence For Side Reactions from Polymer Structure and Number Average Molecular Weights”, J. Am. Chem. Soc., Vol. 85, p. 1580-1854. High levels of branching are associated with favorable properties such as reduced crystallinity, which leads to in better clarity.

To obtain (e.g. sodium or zinc neutralized) ionomers useful in the nanofilled ionomer compositions, the precursor acid copolymers are neutralized with for example a sodium or zinc-containing base to provide an ionomer wherein at least a portion of the hydrogen atoms of carboxylic acid groups of the precursor acid copolymer are replaced by metal cations. Preferably, about 1% to about 100%, about 5% to about 45%, about 5% to about 40%, about 10% to about 35%, or about 15% to about 30% of the hydrogen atoms of carboxylic acid groups of the precursor acid are replaced by metal cations. That is, the acid groups are neutralized to a level of about 1% to about 100%, or preferably about 5% to about 40%, based on the total carboxylic acid content of the precursor acid copolymers as calculated or measured for the non-neutralized precursor acid copolymers. The preferable neutralization ranges make it possible to obtain an ionomer sheet with the desirable end use properties that are novel characteristics of the compositions of the invention, such as low haze, high clarity, sufficient impact resistance and low creep, while still maintaining melt flow that is sufficiently high so that the ionomer can be processed or formed into sheets. The precursor acid copolymers may be neutralized as disclosed, for example, in U.S. Pat. No. 3,404,134.

Unless indicated otherwise, melt flow rate (MFR) was determined in accordance with ASTM method D1238 at 190° C. and 2.16 kg. The precursor acid copolymer may have a MFR of about 0.1 g/10 min or about 0.7 g/10 min to about 30 g/10 min, about 45 g/10 min, about 55 g/10 min, or about 60 g/10 min, or about 100 g/10 min. After neutralization, the MFR of the ionomer may be from about 0.1 to about 60 g/10 min., such as about 1.5 to about 30 g/10 min. The ionomer therefrom may have a melt flow rate of about 30 g/10 min or less, preferably about 5 g/10 min or less.

Of note are precursor acid copolymers having a melt flow rate (MFR) of about 30 g/10 min or less. After neutralization, the MFR can be less than 5 grams/10 min, and possibly less than 2.5 g/10 min or less than 1.5 g/10 min. Suitable ionomers made by neutralizing these precursor acid copolymers with a sodium-containing base have a MFR of about 2 g/10 min or less. Of note are ionomers wherein (i) the precursor α-olefin carboxylic acid copolymer has a MFR of about 30 g/10 min or less; (ii) the precursor α-olefin carboxylic copolymer comprises about 21 to about 23 weight % of copolymerized units of the α,β-ethylenically unsaturated carboxylic acid; (iii) about 20% to about 35% of total content of the carboxylic acid groups present in the precursor α-olefin carboxylic have been neutralized with alkali metal ions; and (iv) the ionomer has a MFR of about 5 g/10 min or less.

Also of note are precursor acid copolymers having a melt flow rate (MFR) of about 100 g/10 min or less (such as about 60 g/10 min). Suitable ionomers made by neutralizing these precursor acid copolymers with a zinc-containing base have a MFR of about 30 g/10 min or less, such as about 3 to about 27 g/10 min. Of note are ionomers wherein (i) the precursor α-olefin carboxylic acid copolymer has a MFR of about 60 g/10 min or less; (ii) the precursor α-olefin carboxylic copolymer comprises about 18 to about 20 weight % of copolymerized units of the α,β-ethylenically unsaturated carboxylic acid; (iii) about 10% to about 15% of total content of the carboxylic acid groups present in the precursor α-olefin carboxylic have been neutralized with alkali metal ions; and (iv) the ionomer has a MFR of about 25 g/10 min or less.

The ionomers may also preferably have a flexural modulus greater than about 40,000 psi (276 MPa), more preferably greater than about 50,000 psi (345 MPa), and most preferably greater than about 60,000 psi (414 MPa), as determined in accordance with ASTM method D638. Ionomers described above do not readily disperse in water.

Some examples of suitable sodium ionomers are also disclosed in U.S. Patent Application Publication 2006/0182983.

Water dispersable ionomers comprise or consist essentially of an ionomer derived from a parent acid copolymer that comprises copolymerized units of ethylene and about 18 to about 30 weight % of copolymerized units of acrylic acid or methacrylic acid, based on the total weight of the parent acid copolymer. The parent acid copolymer has a melt flow rate (MFR) from about 200 to about 1000 g/10 min, measured according to ASTM D1238 at 190° C. with a 2160 g load. About 50% to about 70% of the carboxylic acid groups of the parent acid copolymer, based on the total carboxylic acid content of the parent acid copolymer as calculated for the non-neutralized parent acid copolymer, are neutralized to form the water dispersible ionomer, which includes carboxylic acid salts comprising sodium cations, potassium cations or a combination of sodium cations and potassium cations. The resulting water dispersable ionomer has a MFR from about 1 to about 20 g/10 min.

The nanofilled ionomer compositions useful as polymeric sheets further contain a nanofiller. The nanofiller may be present at a level of about 3 to about 70 weight %, based on the total weight of the nanofilled ionomer composition, preferably from about 5 to about 20 weight %, more preferably from about 5 to about 12 weight %.

Suitable nanofillers are described in the patent application entitled “IONOMER COMPOSITE,” filed concurrently herewith (PCT Application Serial Number PCT/US13/64207, filed Oct. 10, 2013) and incorporated herein by reference. Briefly, however, the nanofillers or nanomaterials suitable for use as the second component of the nanofilled ionomer composition typically have a particle size of from about 0.9 to about 200 nm in at least one dimension, preferably from about 0.9 to about 100 nm. The shape and aspect ratio of the nanofiller may vary, including forms such as plates, rods, or spheres.

The average particle size of layered silicates can be measured, for example using optical microscopy, transmission electron spectroscopy (TEM), or atomic force microscopy (AFM).

Preferred nanofillers for creep resistance include rodlike, platy and layered nanofillers. The nanofillers may be naturally occurring or synthetic materials. In one embodiment, the nanofillers are selected from nano-sized silicas, nanoclays, and carbon nanofibers. Exemplary nano-sized silicas include, but are not limited to, fumed silica, colloidal silica, fused silica, and silicates. Exemplary nanoclays include, but are not limited to, smectite (e.g., aluminum silicate smectite), hectorite, fluorohectorite, montmorillonite (e.g., sodium montmorillonite, magnesium montmorillonite, and calcium montmorillonite), bentonite, beidelite, saponite, stevensite, sauconite, nontronite, and illite. Of note is sepiolite, which is rod-shaped and imparts favorable thermal and mechanical properties. The carbon nanofibers used here may be single-walled nanotubes (SWNT) or multi-walled nanotubes (MWNT). Suitable carbon nanofibers are commercially available, such as those produced by Applied Sciences, Inc. (Cedarville, Ohio) under the tradename Pyrograf™. Nanofillers may also be produced from hydromica or sericite.

As used herein, “aspect ratio” is the square root of the product of the lateral dimensions (area) of a platelet filler particle divided by the thickness of the platelet. Platelets with aspect ratio greater than 25, such as greater than 50, greater than 1,000 or greater than 5,000, are considered herein to have a “high aspect ratio”. Since there will be a distribution of different particles in a sampling of nanofiller, aspect ratio as used herein is based on the average of the primary exfoliated individual particles in the distribution. An exfoliated nanofiller may likely have residual tactoids that may be several primary platelets thick (e.g. 10-20 nanometers thick)

“Effective aspect ratio” relates to the behavior of the platelet filler in a binder. Platelets in a binder may not exist in a single platelet formation. If the platelets are not in a single layer in the binder, the aspect ratio of an entire bundle, aggregate or agglomerate of platelet fillers in a binder is less than that of the individual platelet. Additional discussion of these terms may be found in U.S. Pat. No. 6,232,389.

Nanofillers that are layered silicates or “phyllosilicates” are of particular note. Preferably, the layered silicates are obtained from micas or clays or from a combination of micas and clays. Preferred layered silicates include, without limitation, pyrophillite, talc, muscovite, phlogopite, lepidolithe, zinnwaldite, margarite, hydromuscovite, hydrophlogopite, sericite, montmorillonite, nontronite, hectorite, saponite, vermiculite, sudoite, pennine, klinochlor, kaolinite, dickite, nakrite, antigorite, halloysite, allophone, palygorskite, and synthetic clays such as Laponite™ and the like that are derived from hectorite, clays that are related to hectorite, or talc. More preferably, the layered silicates are obtained from hectorite, fluorohectorite, pyrophillite, muscovite, phlogopite, lepidolithe, zinnwaldite, hydromuscovite, hydrophlogopite, sericite, montmorillonite, vermiculite, kaolinite, dickite, nakrite, antigorite or halloysite. Still more preferably, the layered silicates comprise materials based on or derived from hectorite, muscovite, phlogopite, pyrophyllite and zinnwaldite, for example synthetic layered silicates, hydrous sodium lithium magnesium silicates, and hydrous sodium lithium magnesium fluorosilicates based on hectorite. Also of particular note are muscovite and synthetic clays that are based on muscovite. The nanofiller clays may optionally further comprise ionic fluorine, covalently bound fluorine, other cations aside from those in the natural clays, or sodium pyrophosphate.

More preferred layered silicates include synthetic hectorites such as Laponite™ synthetic layered silicate, available from Rockwood Additives (Southern Clay Products, Gonzales, Tex.). One such nanofiller, marketed under the tradename Laponite™ OG, is a Type 2 sodium magnesium silicate with a cation exchange capacity of about 60 meq/100 g and platelets with an average size of about 83 nm long and 1 nm thick. More generally, preferred synthetic hectorites, such as Laponite™, have a particle size that is at least 50 nm in its largest dimension, or more preferably about 80 to about 100 nm. The average aspect ratio of the preferred synthetic hectorites is about 80 to about 100, although aspect ratios of about 300 may also be suitable. Clays, including synthetic hectorites, may be characterized by their cation exchange capacity. The preferred synthetic hectorites have a cation exchange capacity that is preferably less than 80 meq/100 g, more preferably less than 70 meq/100 g, and still more preferably less than 65 meq/100 g. Moreover, preferred synthetic hectorites have a low content of fluorine, preferably with less than 1 weight %, more preferably less than 0.1 weight %, and still more preferably less than 0.01 weight %, based on the total weight of the synthetic hectorite.

The surface of the layered silicates may be treated with surfactants or dispersants. Often, no such treatment is necessary or desirable. Preferably, when a surface treatment is used, the dispersant or surfactant does not comprise quaternary ammonium ions. These materials may degrade under processing conditions, lending an undesired color to the encapsulant. Tetrasodium pyrophosphate (TSPP) is a notable dispersant, however. When used as a surface treatment for layered silcates, the amount of the TSPP is 15 weight % or less, preferably 10 weight % or less, and more preferably 7 weight % or less, based on the total weight of the layered silicate.

Preferably, the nanofiller particles are comminuted, disintegrated or exfoliated to thin plate-like particles by suitable methods such as calcining or milling “Exfoliation” is the separation of individual layers of the platelet particles and the initial close-range order within the phyllosilicates is lost in this exfoliation process. The filler material used is at least partially exfoliated (at least some particles are separated into a single layer) and preferably is substantially exfoliated (the majority of the particles are separated into a single layer).

These processes produce smaller, thinner particles with higher aspect ratios. The smaller particles produce a clearer nanocomposite with increased enhancement of the desirable mechanical properties. The neat (“dry”) nanoparticles may be exfoliated, or the nanoparticles may be exfoliated in a suspension, such as a suspension in water, in another polar solvent, in oil, or in any combination of two or more suspension media. The comminution, disintegration, or exfoliation may be performed by any mechanical or thermal method, or by a combination of thermal and mechanical methods, for example using a stirrer, a sonicator, a homogenizer, or a rotor-stator. Preferably, the nanofiller is a layered silicate that is thoroughly exfoliated (i.e., de-layered or split) to form individual nanoparticles or small aggregates of a few nanoparticles in each.

In many embodiments, the layered silicates do not have any significant coloring tone. Also notable are layered silicates that do not have a coloring tone that is discernible to the naked eye and layered silicates that do not have a coloring tone that influences the color of the polymer matrix significantly. Preferably, the layered silicates are thoroughly comminuted, disintegrated or exfoliated from the form in which they are supplied.

For layered silicate nanofillers, the mean thickness of an individual platelet is about 1 nm and the mean length or width is in the range of about 25 nm to about 500 nm. For Laponite™ which is smaller and has a lower aspect ratio, the mean length or width is preferably from about 40 nm to about 200 nm, and more preferably from about 75 to about 110 nm. The clay particles preferably show an average aspect ratio in the range of from about 10 to about 8000, from about 30 to about 2000 or from about 50 to about 500, and more preferably the average aspect ratio is about 30 to about 150. It is preferred that the clays used in the composition be able to hydrate to form gels or sols. Transparent, colorless clays are preferred, as they minimize adverse effects on the performance of the solar modules.

The use of encapsulants that are nanofilled ionomeric materials, as described herein, will enhance the upper end-use temperature of the solar cell modules that include these encapsulants, because the nanofilled ionomeric materials also have reduced creep at elevated temperatures. The end-use temperature of the modules may be enhanced by up to about 20° C. to about 70° C., or by a greater amount. Also advantageously, because the nanofilled ionomer compositions remain thermoplastic, the encapsulants described herein have improved recyclability with respect to encapsulant materials that exhibit low creep because they have been crosslinked. Moreover, because of their small particle size, nanofillers will not significantly affect the optical properties of the encapsulant sheets.

For example, the nanofillers effectively reduce the melt flow of the ionomer composition, while still allowing production of thermoplastic films or sheets. In addition, solar cell modules having an encapsulant that comprises nanofilled ionomeric materials will be more fire resistant than solar cell modules having a conventional ionomeric encapsulant. The reason is that the nanofilled ionomeric polymers have a reduced tendency to flow out of the laminate, which in turn, could reduce the available fuel in a fire situation.

Suitable methods for the synthesis of ionomer nanocomposites are described in detail in the abovementioned concurrently filed patent application (PCT Application Serial Number PCT/US13/64207) and in U.S. Pat. No. 7,759,414. Briefly, however, in the field of nanocomposites, attaining a homogeneous composite, i.e., a high degree of nanoparticle dispersion within the polymer matrix, is essential for achieving target performance. It is known that certain neat nanoparticles may be added directly to a neat ionomer, then dispersed and deagglomerated, preferably using a high-shear melt mixing process. It is also known for a relatively high amount of nanofiller to be dispersed in a relatively small amount of polymer to form a “masterbatch” which is subsequently diluted with a polymer matrix that may be the same as or different from the polymer in the masterbatch.

A preferred concentrated nanofiller masterbatch composition comprises (a) a water dispersable ionomer (as described above) and (b) a nanofiller. An aqueous dispersion of the water dispersable ionomer can be prepared by mixing the solid ionomer under low shear conditions with water heated to a temperature of from about 80 to about 90° C. Additional information regarding suitable water dispersable ionomers and the preparation of suitable aqueous ionomer dispersions is disclosed in U.S. application Ser. No. 13/589,211. The aqueous ionomer dispersion can be mixed with the nanofiller, also under low shear conditions at about 80 to about 90° C., followed by evaporation of the water to provide a solid ionomer/nanofiller masterbatch.

The concentrated nanofiller masterbatch may comprise about 10 to about 95 weight %, about 20 to about 90 weight %, about 30 to about 90 weight %, about 40 to about 75 weight %, or about 50 to about 60 weight % of the water dispersable ionomer and about 5 to about 70 weight %, about 10 to about 70 weight %, about 20 to about 70 weight %, about 25 to about 60 weight %, or about 30 to about 50 weight % of the nanofiller, based on the total weight of the masterbatch composition.

One preferred method for preparing the concentrated nanofiller masterbatch is a solvent process comprising the steps of (a) dispersing nanofillers in a selected solvent such as water, optionally using a dispersant or surfactant; (b) dissolving a solid water dispersable ionomer in the same solvent system; (c) combining the solution and the dispersion; and (d) removing the solvent.

In another preferred process for preparing a concentrated nanofiller masterbatch, pellets or powder of a solid water dispersable ionomer and nanofiller powder are metered into the first feed port of an extruder. The solid mixture is conveyed to the extruder's melting zone, where the ionomer is melted by mechanical energy input from the rotating screws and heat transfer from the barrel, and where high stresses break down the nanofiller agglomerate particles. Liquid water (typically deionized) is pumped into the melted mixture, for example under pressure through an injection port in the extruder. The melted mixture is conveyed to a region of the extruder that is open to the atmosphere or under vacuum pressure, where some or all of the water evaporates or diffuses out of the mixture. This evaporation or diffusion step may optionally be repeated once or more. The resulting viscous polymer melt with well dispersed nanoparticles is removed from the extrudate; for example, it may be pumped by the screws and extruded through a shaping die. Should further processing under high-shear melt-mixing conditions be required to improve the dispersion quality, the extruded material may optionally be fed to the extruder and reprocessed, again optionally with water injection and removal.

The concentrated nanofiller masterbatch can be blended with the ionomer that forms the bulk of the polymeric matrix to produce the nanofilled ionomeric material. These nanocomposite compositions may be prepared using a melt process, which includes combining all the components of the nanofilled ionomeric composition, including the masterbatch, the bulk ionomer and additional optional additives, if any. These components are melt compounded at a temperature of about 130° C. to about 230° C., or about 170° C. to about 210° C., to form a uniform, homogeneous blend. The process may be carried out using stirrers, Banbury™ type mixers, Brabender PlastiCorder™ type mixers, Haake™ type mixers, extruders, or other suitable equipment.

Methods for recovering the homogeneous ionomeric nanocomposite produced by melt compounding will depend on the particular piece of melt compounding apparatus utilized and may be determined by those skilled in the art. For example, if the melt compounding step takes place in a mixer such as a Brabender PlastiCorder™ mixer, the homogeneous nanocomposite may be recovered from the mixer as a single mass. If the melt compounding step takes place in an extruder, the homogeneous nanocomposite will be recovered after it exits the extruder die in a form (sheet, filament, pellets, etc.) that is determined by the shape of the die and any post-extrusion processing (such as embossing, cutting, or calendaring, e.g.) that may be applied.

Accordingly, a suitable process for preparing the nanofilled ionomer composition comprises
(1) mixing a solid water dispersable ionomer composition comprising a water dispersible ionomer, as described above, with water heated to a temperature of from about 80 to about 90° C. to provide a heated aqueous ionomer dispersion;
(2) optionally cooling the aqueous ionomer dispersion;
(3) mixing the aqueous ionomer dispersion with one or more nanofillers to provide an aqueous dispersion of ionomer and nanofiller;
(4) removing the water from the aqueous dispersion of ionomer and nanofiller to provide a mixture of water dispersable ionomer and nanofiller in solid form;
(5) melt blending the mixture of water dispersable ionomer and nanofiller with another ionomer that is described above as suitable for use in the nanofilled ionomeric composition, specifically an ionomer that is an ionic, neutralized derivative of a precursor α-olefin carboxylic acid copolymer, wherein about 10% to about 35% of the total content of the carboxylic acid groups present in the precursor α-olefin carboxylic acid copolymer is neutralized to form salts containing alkali metal cations, alkaline earth metal cations, transition metal cations, or combinations of two or more of these metal cations, and wherein the precursor α-olefin carboxylic acid copolymer comprises (i) copolymerized units of an α-olefin having 2 to 10 carbons and (ii) about 15 to about 25 weight %, based on the total weight of the precursor α-olefin carboxylic acid copolymer, of copolymerized units of an α,β-ethylenically unsaturated carboxylic acid having 3 to 8 carbons, wherein the ionomer has a melt flow rate (MFR) of about 0.1 g/10 min to about 100 g/10 min, as determined in accordance with ASTM method D1238 at 190° C. and 2.16 kg load.

Another suitable process for preparing the nanofilled ionomer composition comprises forming a concentrated nanofiller masterbatch in an extruder using water and a solid water dispersable ionomer, as described above; optionally removing the concentrated nanofiller masterbatch from the equipment, cooling it and forming it into a convenient shape, such as pellets; and melt blending the concentrated nanofiller masterbatch with another ionomer that is described above as suitable for use in the nanofilled ionomeric composition, such as the ionomer described immediately above with respect to the aqueous dispersion process.

Accordingly, a preferred nanofilled ionomer composition for use in the solar cell modules comprises:

(1) an alkali metal ionomer that is an ionic, neutralized derivative of an ethylene carboxylic acid copolymer, wherein about 10% to about 35% of the total content of the carboxylic acid groups present in the precursor ethylene carboxylic acid copolymer are neutralized with alkali metal ions such as sodium, potassium or combinations thereof, and wherein the precursor ethylene carboxylic acid copolymer comprises (i) copolymerized units of ethylene and (ii) about 20 to about 25 weight %, based on the total weight of the ethylene carboxylic acid copolymer, of copolymerized units of an α,β-ethylenically unsaturated carboxylic acid having 3 to 8 carbons; having a melt flow rate (MFR) of about 2.5 g/10 min or less;

(2) nanofiller; and

(3) a second ionomer comprising a parent acid copolymer that comprises copolymerized units of ethylene and about 18 to about 30 weight % of copolymerized units of acrylic acid or methacrylic acid, based on the total weight of the parent acid copolymer, the acid copolymer having a melt flow rate (MFR) from about 200 to about 1000 g/10 min., wherein about 50% to about 70% of the carboxylic acid groups of the copolymer, based on the total carboxylic acid content of the parent acid copolymer as calculated for the non-neutralized parent acid copolymer, are neutralized to carboxylic acid salts comprising sodium cations, potassium cations or a combination thereof; and the second ionomer has a MFR from about 1 to about 20 g/10 min. measured according to ASTM D1238 at 190° C. with a 2.16 kg load.

Another preferred nanofilled ionomer composition for use in the solar cell modules comprises:

(1) an ionomer that is an ionic, neutralized derivative of an ethylene carboxylic acid copolymer, wherein about 10% to about 35%, such as about 10 to about 15%, of the total content of the carboxylic acid groups present in the precursor ethylene carboxylic acid copolymer are neutralized with zinc ions, and wherein the precursor ethylene carboxylic acid copolymer comprises (i) copolymerized units of ethylene and (ii) about 18 to about 20 weight %, based on the total weight of the ethylene carboxylic acid copolymer, of copolymerized units of an α,β-ethylenically unsaturated carboxylic acid having 3 to 8 carbons; having a melt flow rate (MFR) of about 30 g/10 min or less, such as about 3 to about 27 g/10 min;

(2) nanofiller; and

(3) a second ionomer comprising a parent acid copolymer that comprises copolymerized units of ethylene and about 18 to about 30 weight % of copolymerized units of acrylic acid or methacrylic acid, based on the total weight of the parent acid copolymer, the acid copolymer having a melt flow rate (MFR) from about 200 to about 1000 g/10 min., wherein about 50% to about 70% of the carboxylic acid groups of the copolymer, based on the total carboxylic acid content of the parent acid copolymer as calculated for the non-neutralized parent acid copolymer, are neutralized to carboxylic acid salts comprising sodium cations, potassium cations or a combination thereof; and the second ionomer has a MFR from about 1 to about 20 g/10 min. measured according to ASTM D1238 at 190° C. with a 2.16 kg load.

The extent of dispersion of the nanofiller in the polymer matrix can be measured by X-ray diffraction. For example, X-ray diffraction (XRD) is commonly used to determine the interlayer spacing (d-spacing) of silicate layers in silicate-containing nanocomposites. When X-rays are scattered from the silicate platelets, peaks of the scattered intensity are observed corresponding to the clay structure. Based on Bragg's law, the interlayer spacing, i.e., the distance between two adjacent clay platelets, can be determined from the peak position of the XRD pattern. When interaction of nanoclay and polymer matrix occurs, and the polymer is inserted between the layers of clay, the interlayer spacing increases, and the reflection peak of the XRD pattern moves to a lower 2-THETA position. Under such conditions, the nanoclay is considered to be intercalated.

The masterbatch and the nanofilled ionomer composition may also contain other additives known in the art. Suitable additives include, but are not limited to, processing aids, flow enhancing additives, lubricants, pigments, dyes, flame retardants, impact modifiers, nucleating agents, anti-blocking agents such as silica, thermal stabilizers, UV absorbers, UV stabilizers, dispersants, surfactants, chelating agents, coupling agents, reinforcement additives, such as glass fiber, fillers and the like. Four notable additives are thermal stabilizers, UV absorbers, hindered amine light stabilizers (HALS), and silane coupling agents. Suitable and preferred examples of these additives and suitable and preferred levels of these additives are set forth in U.S. Patent Application Publication 2010/0112253. Generally, additives that may reduce the optical clarity of the composition, such as reinforcement additives and fillers, are reserved for those sheets that are used as the back encapsulants.

The compositions are most preferably made without use of organic peroxides, crosslinking agents or initiators (so that the sheets and the interlayers of the laminates do not contain organic peroxides and are not crosslinked).

The sheet that functions as one component of the solar modules described herein may be in a single layer or in multilayer form. By “single layer”, it is meant that the sheet is made of or consists essentially of the nanofilled ionomer composition. When in a multilayer form, at least one of the sub-layers of the sheet is made of or consists essentially of the nanofilled ionomer composition, while the other sub-layer(s) may be made of any other suitable polymeric material(s), such as, for example, acid copolymers as previously defined herein, ionomers as previously defined herein, poly(ethylene vinyl acetates), poly(vinyl acetals) (including acoustic grade poly(vinyl acetals)), polyurethanes, polyvinylchlorides, polyethylenes (e.g., linear low density polyethylenes), polyolefin block elastomers, copolymers of α-olefins and α,β-ethylenically unsaturated carboxylic acid esters (e.g., ethylene methyl acrylate copolymers and ethylene butyl acrylate copolymers), silicone elastomers, epoxy resins, and combinations of two or more thereof.

The total thickness of the sheet that comprises at least one layer of the nanofilled ionomer composition may be in the range of about 10 to about 90 mil (about 0.25 to about 2.3 mm), preferably about 10 to about 60 mil (about 0.25 to about 1.5 mm), more preferably about 15 to about 55 mil (about 0.38 to about 1.4 mm), yet more preferably about 15 to about 45 mil (about 0.38 to about 1.14 mm), yet more preferably about 15 to about 35 mil (about 0.38 to about 0.89 mm), and most preferably about 18 to about 35 mil (about 0.64 to about 0.89 mm). When in multilayer form, the thickness of the individual sub-layers of the nanofilled encapsulant layer is not critical and may be independently varied depending on the requirements of the particular application.

The sheet comprising the nanofilled ionomer composition may have a smooth or rough surface on one or both sides. Preferably, the sheet has rough surfaces on both sides to facilitate deaeration during the lamination process. Rough surfaces can be created by mechanically embossing or by melt fracture during extrusion of the sheets followed by quenching so that surface roughness is retained during handling. The surface pattern can be applied to the sheet through processes that are commonly known in the art. For example, the as-extruded sheet may be passed over a specially prepared surface of a die roll positioned in close proximity to the exit of the die which imparts the desired surface characteristics to one side of the molten polymer. Thus, when the surface of such a die roll has minute peaks and valleys, the polymer sheet cast thereon will have a rough surface on the side that is in contact with the roll, and the rough surface generally conforms respectively to the valleys and peaks of the roll surface. Such die rolls are disclosed in, e.g., U.S. Pat. No. 4,035,549 and U.S. Patent Publication 2003/0124296.

The sheets comprising the nanofilled ionomer composition can be produced by any suitable process. For example, the sheets may be formed through dipcoating, solution casting, compression molding, injection molding, lamination, melt extrusion, blown film, extrusion coating, tandem extrusion coating, or by any other procedures that are known to those of skill in the art. Preferably, the sheets are formed by melt extrusion, melt coextrusion, melt extrusion coating, or tandem melt extrusion coating processes.

Provided herein is a solar cell module comprising at least one layer that is a sheet (i.e. encapsulant layer) comprising at least one layer of the above-described nanofilled ionomer composition and a solar cell layer comprised of one or a plurality of solar cells.

The term “solar cell” as used herein includes any article which can convert light into electrical energy. Solar cells useful in the invention include, but are not limited to, wafer-based solar cells (e.g., c-Si or mc-Si based solar cells, as described above in the background section) and thin film solar cells (e.g., a-Si, μc-Si, CdTe, or CI(G)S based solar cells, as described above in the background section). Within the solar cell layer, it is preferred that the solar cells be electrically interconnected or arranged in a flat plane. In addition, the solar cell layer may further comprise electrical wirings, such as cross ribbons and bus bars.

The solar cell module comprises at least one layer of a sheet comprising the nanofilled ionomer composition, which is laminated to the solar cell layer and serves as an encapsulant layer. The term “laminated”, as used herein, for example to refer to layers within a laminated structure, refers to two layers are bonded either directly (i.e., without any additional material between the two layers) or indirectly (i.e., with additional material, such as interlayer or adhesive materials, between the two layers). Preferably, the sheet comprising the nanofilled ionomer composition is directly laminated or bonded to the solar cell layer.

Of note is a solar cell module wherein the solar cell layer has a light-receiving and non-light-receiving side and which comprises a front encapsulant layer laminated to the light-receiving side of the solar cell layer and a back encapsulant layer laminated to the non-light-receiving side of the solar cell layer, wherein at least one of the front and back encapsulant layers comprises the nanofilled ionomer composition.

The solar cell module may further comprise additional encapsulant layers comprising other polymeric materials, such as for example acid copolymers as previously defined herein, ionomers as previously defined herein, poly(ethylene vinyl acetates), poly(vinyl acetals) (including acoustic grade poly(vinyl acetals)), polyurethanes, poly(vinyl chlorides), polyethylenes (e.g., linear low density polyethylenes), polyolefin block elastomers, copolymers of α-olefins and α,β-ethylenically unsaturated carboxylic acid esters) (e.g., ethylene methyl acrylate copolymers and ethylene butyl acrylate copolymers), silicone elastomers, epoxy resins, and combinations of two or more thereof.

The thickness of the individual encapsulant layers other than the sheet(s) comprising the nanofilled ionomer composition may independently range from about 1 mil (0.026 mm) to about 120 mils (3 mm), or preferably from about 1 mil to about 40 mils (1.02 mm), or more preferably from about 1 mil to about 20 mils (0.51 mm). Any or all of the encapsulant layer(s) comprised in the solar cell modules may have smooth or rough surfaces. Preferably, the encapsulant layer(s) have rough surfaces to facilitate deaeration during the lamination process.

The solar cell module may further comprise an incident layer or a backing layer serving as the outermost layer or layers of the module at the light-receiving side and the non-light-receiving side of the solar cell module, respectively.

The outer layers of the solar cell modules, i.e., the incident layer and the backing layer, may be derived from any suitable sheets or films. Suitable sheets may be glass or polymeric sheets, such as those comprising a polymer selected from polycarbonates, acrylics, polyacrylates, cyclic polyolefins (e.g., ethylene norbornene polymers), polystyrenes (preferably metallocene-catalyzed polystyrenes), polyamides, polyesters, fluoropolymers, or combinations of two or more thereof. In addition, metal sheets, such as aluminum, steel, galvanized steel, or ceramic plates may be utilized in forming the backing layer.

The term “glass” includes not only window glass, plate glass, silicate glass, sheet glass, low iron glass, tempered glass, tempered CeO-free glass, and float glass, but also colored glass, specialty glass (such as those containing ingredients to control solar heating), coated glass (such as those sputtered with metals (e.g., silver or indium tin oxide) for solar control purposes), E-glass, Toroglass, Solex® glass (PPG Industries, Pittsburgh, Pa.) and Starphire® glass (PPG Industries). Such specialty glasses are disclosed in, e.g., U.S. Pat. Nos. 4,615,989; 5,173,212; 5,264,286; 6,150,028; 6,340,646; 6,461,736; and 6,468,934. It is understood, however, that the type of glass to be selected for a particular module depends on the intended use.

Suitable film layers comprise polymers that include but are not limited to, polyesters (e.g., poly(ethylene terephthalate) and poly(ethylene naphthalate)), polycarbonate, polyolefins (e.g., polypropylene, polyethylene, and cyclic polyolefins), norbornene polymers, polystyrene (e.g., syndiotactic polystyrene), styrene-acrylate copolymers, acrylonitrile-styrene copolymers, polysulfones (e.g., polyethersulfone, polysulfone, etc.), polyamides, poly(urethanes), acrylics, cellulose acetates (e.g., cellulose acetate, cellulose triacetates, etc.), cellophane, poly(vinyl chlorides) (e.g., poly(vinylidene chloride)), fluoropolymers (e.g., polyvinyl fluoride, polyvinylidene fluoride, polytetrafluoroethylene, ethylene-tetrafluoroethylene copolymers, etc.) and combinations of two or more thereof. The polymeric film may be bi-axially oriented polyester film (preferably poly(ethylene terephthalate) film) or a fluoropolymer film (e g, Tedlar®, Tefzel®, and Teflon® films, from E. I. du Pont de Nemours and Company, Wilmington, Del. (DuPont)). Fluoropolymer-polyester-fluoropolymer (e.g., “TPT”) films are also preferred for some applications. Metal films, such as aluminum foil, may also be used as the backing layers.

The solar cell module may further comprise other functional film or sheet layers (e.g., dielectric layers or barrier layers) embedded within the module. Such functional layers may be derived from any of the above mentioned polymeric films or those that are coated with additional functional coatings. For example, poly(ethylene terephthalate) films coated with a metal oxide coating, such as those disclosed in U.S. Pat. Nos. 6,521,825 and 6,818,819 and European Patent EP1182710, may function as oxygen and moisture barrier layers in the laminates.

If desired, a layer of nonwoven glass fiber (scrim) may also be included between the solar cell layers and the encapsulants to facilitate deaeration during the lamination process or to serve as reinforcement for the encapsulants. The use of such scrim layers is disclosed in, e.g., U.S. Pat. Nos. 5,583,057; 6,075,202; 6,204,443; 6,320,115; and 6,323,416 and European Patent EP0769818.

The film or sheet layers positioned to the light-receiving side of the solar cell layer are preferably made of transparent material to allow efficient transmission of sunlight into the solar cells. The light-receiving side of the solar cell layer may sometimes be referred to as a front side and in actual use conditions would generally face a light source. The non-light-receiving side of the solar cell layer may sometimes be referred to as a lower or back side and in actual use conditions would generally face away from a light source. A special film or sheet may be included to serve both the function of an encapsulant layer and an outer layer. It is also conceivable that any of the film or sheet layers included in the module may be in the form of a pre-formed single-layer or multi-layer film or sheet. Another suitable type of solar cell module is designed so that both of its sides are transparent and positioned to receive light that is transmitted to the solar cell layer.

If desired, one or both surfaces of the incident layer films and sheets, the backing layer films and sheets, the encapsulant layers and other layers incorporated within the solar cell module may be treated prior to the lamination process to enhance the adhesion to other laminate layers. This adhesion enhancing treatment may take any form known in the art and includes those set forth in U.S. Patent Application Publication 2010/0108126.

In one particular embodiment, in which the solar cells are derived from wafer-based self supporting solar cell units, the solar cell module may comprise, in order of position from the front light-receiving side to the back non-light-receiving side, (a) an incident layer, (b) a front encapsulant layer, (c) a solar cell layer comprised of one or more electrically interconnected solar cells, (d) a back encapsulant layer, and (e) a backing layer, wherein at least one or both of the front and back encapsulant layers comprises the nanofilled ionomer composition comprising sheets.

Preferably, however, the solar cell modules are derived from thin film solar cells and may (i) in one embodiment, comprise, in order of position from the front light-receiving side to the back non-light-receiving side, (a) a solar cell layer comprising a superstrate and a layer of thin film solar cell(s) deposited thereon at the non-light-receiving side, (b) a (back) encapsulant layer comprising the nanofilled ionomer composition comprising sheet, and (c) a backing layer or (ii) in a more preferred embodiment, comprise, (a) a transparent incident layer, (b) a (front) encapsulant layer comprising the nanofilled ionomer comprising sheet, and (c) a solar cell layer comprising a layer of thin film solar cell(s) deposited on a substrate at the light-receiving side thereof.

Moreover, a series comprising two or more of the solar cell modules described above may be further linked to form a solar cell array, which can produce a desired voltage and current. The solar cell modules in the array may be the same or different.

Any lamination process known in the art (such as an autoclave or a non-autoclave process) may be used to prepare the solar cell modules. In an example of a suitable process, the component layers of the solar cell module are stacked in the desired order to form a pre-lamination assembly. The assembly is then placed into a bag capable of sustaining a vacuum (“a vacuum bag”), the air is drawn out of the bag by a vacuum line or other means, the bag is sealed while the vacuum is maintained (e.g., at least about 27 to 28 inches of Hg (689-711 mm Hg)), and the sealed bag is placed in an autoclave at a pressure of about 150 to about 250 psi (about 11.3 to about 18.8 bar), a temperature of about 130° C. to about 180° C., or about 120° C. to about 160° C., or about 135° C. to about 160° C., or about 145° C. to about 155° C., for about 10 to about 50 min, or about 20 to about 45 min, or about 20 to about 40 min, or about 25 to about 35 min. A vacuum ring may be substituted for the vacuum bag. One type of suitable vacuum bag is disclosed within U.S. Pat. No. 3,311,517. Following the heat and pressure cycle, the air in the autoclave is cooled without adding additional gas to maintain pressure in the autoclave. After about 20 min of cooling, the excess air pressure is vented and the laminates are removed from the autoclave.

Alternatively, the pre-lamination assembly may be heated in an oven at about 80° C. to about 120° C., or about 90° C. to about 100° C., for about 20 to about 40 min, and thereafter, the heated assembly is passed through a set of nip rolls so that the air in the void spaces between the individual layers may be squeezed out, and the edge of the assembly sealed. The assembly at this stage is referred to as a pre-press.

The pre-press may then be placed in an air autoclave where the temperature is raised to about 120° C. to about 160° C., or about 135° C. to about 160° C., at a pressure of about 100 to about 300 psi (about 6.9 to about 20.7 bar), or preferably about 200 psi (13.8 bar). These conditions are maintained for about 15 to about 60 min, or about 20 to about 50 min, after which the air is cooled while no further air is introduced to the autoclave. After about 20 to about 40 min of cooling, the excess air pressure is vented and the laminated products are removed from the autoclave.

The solar cell modules may also be produced through non-autoclave processes. Such non-autoclave processes are disclosed, e.g., in U.S. Pat. Nos. 3,234,062; 3,852,136; 4,341,576; 4,385,951; 4,398,979; 5,536,347; 5,853,516; 6,342,116; and 5,415,909, U.S. Patent Publication 2004/0182493, European Patent EP1235683 B1, and PCT Patent Publications WO91/01880 and WO03/057478. Generally, the non-autoclave processes include heating the pre-lamination assembly and the application of vacuum, pressure or both. For example, the assembly may be successively passed through heating ovens and nip rolls. Particularly useful processes include vacuum lamination using, for example, Meier or Burkle laminators.

These examples of lamination processes are not intended to be limiting. Essentially any lamination process may be used.

In this connection, the encapsulant sheets are generally supplied as sheets having a substantially uniform thickness. When the encapsulant sheets are laid up with the solar cell assembly in the pre-press assembly, there may be gaps or voids where portions of the solar cell assembly are not in contact with the encapsulant sheets. During the lamination process, however, the polymeric encapsulant sheets melt or soften to some degree. Under the pressure that is applied during the process, the encapsulant also flows around the surface peaks or contours of the solar cell assembly. In addition, the air trapped in the voids is extracted or dissolved during the vacuum or pressure stages of lamination. As is discussed above, the extraction of the trapped air is facilitated when the encapsulant has one or more roughened surfaces. Thus, any voids between the solar cell assembly and the encapsulant sheets are filled during the lamination process to provide solar cell modules in which the encapsulant is in good contact with the solar cell assembly.

If desired, the edges of the solar cell module may be sealed to reduce moisture and air intrusion and potential degradative effects on the efficiency and lifetime of the solar cell(s) by any means disclosed in the art. Suitable edge seal materials include, but are not limited to, butyl rubber, polysulfide, silicone, polyurethane, polypropylene elastomers, polystyrene elastomers, block elastomers, styrene-ethylene-butylene-styrene (SEBS), and the like.

The invention is further illustrated by the following examples of certain embodiments.

### EXAMPLES

The following Examples are intended to be illustrative of the invention, and are not intended in any way to limit the scope of the invention.

### Material and Methods

Ionomers: The ethylene/methacrylic acid dipolymers listed in Table 1 were neutralized to the indicated extent by treatment with NaOH, zinc oxide or KOH using standard procedures to form sodium, zinc or potassium-containing ionomers. Melt flow rates (MFR) were determined in accordance with ASTM D1238 at 190° C. with a 2.16 kg mass.

TABLE 1

| Precursor Copolymer | | | | | |
|---|---|---|---|---|---|
| Methacrylic | | Ionomer | | | |
| acid, | MFR | | | Neutraliza- | MFR |
| weight %* | g/10 min | | Cation | tion Level % | g/10 min |
| 21.7 | 23 | ION-1 | Na⁺ | 26 | 1.8 |
| 19 | 330 | ION-2 | K⁺ | 50 | 4.5 |
| 19 | 60 | ION-3 | Zn⁺² | 11-12 | 25 |

*remainder ethylene
ION-1 and ION-3 are ionomers that are not readily water dispersable. ION-2 is a water dispersable ionomer.

Nanofiller NF-1: a Type 2 sodium magnesium silicate with a cation exchange capacity of about 60 meq/100 g and platelets about 83 nm long and 1 nm thick, commercially available from Rockwood Additives (Southern Clay Products, Gonzales, Tex.) as Laponite™ OG.
Additive UVS-1: a UV-stabilizer commercially available from BASF under the tradename Tinuvin™ 328.

### General Sheeting Process for Preparing Extruded Interlayer Sheets

Pellets of ionomer were fed into a 25 mm diameter Killion extruder using the general temperature profile set forth in Table 2.

TABLE 2

| Extruder Zone | Temperature (° C.) |
|---|---|
| Feed | Ambient |
| Zone 1 | 100-170 |
| Zone 2 | 150-210 |
| Zone 3 | 170-230 |
| Adapter | 170-230 |
| Die | 170-230 |

The polymer throughput was controlled by adjusting the screw speed. The extruder fed a 150 mm slot die with a nominal gap of 2 to 5 mm. The cast sheet was fed onto a 200 mm diameter polished chrome chill roll held at a temperature of between 10° C. and 15° C. rotating at 1 to 2 rpm.

### Comparative Example

### Interlayer Sheet C1

UVS-1 (0.12 weight % based on the amount of polymer) was added to ION-1 in a single screw extruder operating at about 230° C. The resulting mixture was cast into a sheet for subsequent lamination as detailed below. The sheet measured about 0.9 mm thick.

### General Procedure for Preparing Aqueous Dispersions

A round-bottom flask equipped with a mechanical stirrer, a heating mantle, and a temperature probe associated with a temperature controller for the heating mantle was charged with water. The water was stirred and the neat solid ionomer ION-2 was added to the water at room temperature. The aqueous ionomer mixture was stirred at room temperature for 5 minutes and then heated to 80° C. Next, the mixture was stirred for 20 min at 90° C. until the ionomer was fully incorporated into the water, as judged by the clarity of the mixture. The heating mantle and temperature controller were removed from the round-bottom flask, and the aqueous ionomer mixture was cooled to room temperature with continued stirring.

Nanofiller was added as a powder to the aqueous ionomer mixture. During the addition, the aqueous ionomer mixture was stirred rapidly so that the nanofiller was incorporated smoothly without forming dry lumps. Stirring was continued for approximately 30 min until the nanofiller was dispersed, again as judged by the clarity of the mixture.

The aqueous ionomer mixture, with or without dispersed nanofiller, was dried before further use. The round bottom flask was attached to a rotary evaporator to which a house vacuum of about 100 mmHg was applied. The flask was immersed in a water bath at 65° C. and rotated slowly while the temperature bath was gradually raised to a maximum of 85° C. The rotary evaporation under heat and vacuum were continued for one to two days. The solid product was removed from the round bottom flask and further dried for about 16 to 64 hours in an oven at 50° C. under house vacuum (about 120 to 250 mm Hg) with a slowly flowing nitrogen atmosphere.

### Ionomer A

An aqueous dispersion of ION-2 was prepared and dried according to the general aqueous dispersion procedure above, in quantities shown in Table 3. There was no filler in this material.

### Ionomer B

An aqueous dispersion of ION-2 was prepared, mixed with filler NF-1 and dried according to the general aqueous dispersion procedure above, in quantities shown in Table 3.

TABLE 3

| | Ionomer A | Ionomer B |
|---|---|---|
| Deionized water, g | 165.0 | 165.0 |
| ION-2, g | 49.05 | 11.55 |
| NF-1, g | 0 | 4.95 |
| Calculated weight % of NF-1 in dried solids | 0 | 30 |

### General Procedure for Preparing Ionomer Blends

A Brabender PlastiCorder™ Model PL2000 mixer (available from Brabender Instruments Inc. of South Hackensack, N.J.) with Type 6 mixing head and stainless roller blades was heated to 140° C. and mixed at the same temperature. A portion of a solid ionomer (15 g of Ionomer A or of Ionomer B) was melt-blended in the mixer with 30.0 g of ION-1. The materials were mixed at 140° C. for 20 minutes at 75 rpm under a nitrogen blanket delivered through the ram. The blend was removed from the mixer and allowed to cool to room temperature. The two blends are summarized in Table 4. A blend comprising ION-3 and 10 weight % of nanofiller is prepared using a similar procedure by substituting ION-3 for ION-1, blended with Ionomer B.

TABLE 4

| | Comparative Example C2 | Example 1 |
|---|---|---|
| Ionomer A (g) | 15 | 0 |
| Ionomer B (g) | 0 | 15 |
| ION-1 (g) | 30 | 30 |
| Calculated weight % of NF-1 | 0 | 10 |

### Comparative Example C2

### Interlayer Sheet

Two films were formed by molding the blend of Comparative Example C2 (see Table 4) in a hydraulic press at 190° C., incrementally raising the pressure to 152 MPa, and holding the temperature and pressure for 210 seconds, followed by cooling the platens to around 37° C. and removing the resultant films from the mold. The cooled films measured about 0.8 mm thick.

### Example 1

### Interlayer Sheet

Two films were formed by molding the composition of Example 1 (see Table 4) in a hydraulic press at 215° C., incrementally raising the pressure to 152 MPa, and holding the temperature and pressure for 210 seconds, followed by cooling to around 37° C. and removing the resultant films from the mold. Cooled films measured about 0.8 mm thick.

### Glass Laminates

In order to assess the suitability of nanocomposites in solar cell modules, glass laminates were prepared by the Lamination Process described below, using the films of Comparative Examples C1 and C2 and Example 1 to prepare two glass/encapsulant/glass laminates from each of the three interlayer sheets.

Each glass/encapsulant/glass laminate comprised a 102 mm×102 mm film of the encapsulants described above, a 102 mm×204 mm×3 mm (rectangular) bottom glass plate and a 102 mm×102 mm×3 mm (square) top glass plate and were laminated as follows. The glass plates were high clarity, low iron Diamant® float glass from Saint Gobain Glass. Pre-laminates were laid-up with the encapsulant film and the square glass plate coinciding and offset about 25 mm from one of the short edges of the rectangular glass plate. The “tin side” of each glass plate was in contact with the interlayer sheet. These specimens were laminated in a Meier vacuum laminator at 150° C. using a 5-minute evacuation, 1-minute press, 15-minute hold and 30-second pressure release cycle, using nominal “full” vacuum (0 mBar) and 800 mBar pressure.

### Creep Test

The glass laminates were tested for heat deformation or “creep.” Each laminate was hung from the top rack of an air oven by the 25-mm exposed edge of the larger glass plate using binder clips. The oven was preheated to 105° C. or to 115° C. The other end of the larger glass plate rested on a catch pan to prevent the laminate from slipping out of the binder clips. With this mounting system, the rectangular glass plate was constrained in a vertical position while the encapsulant and square glass plate were unsupported and unconstrained. The vertical displacement of the smaller glass plates was measured periodically and reported in Table 5.

TABLE 5
Vertical Displacement in mm

| | | | |
|---|---|---|---|
| | Comparative | Comparative | |
| Time (hours) | Example C1 | Example C2 | Example 1 |

T = 105° C.

| | | | |
|---|---|---|---|
| 2.5 | 0 | 0 | 0 |
| 6 | 0 | 0 | 0 |
| 24 | 2 | 2 | 0 |
| 48 | 6 | 5 | 0 |
| 120 | 8 | 7 | 0 |
| 168 | 10 | 9 | 0 |
| 200 | 12 | 10 | 0 |

T = 115° C.

| | | | |
|---|---|---|---|
| 2.5 | 0 | 0 | 0 |
| 6 | 1 | 1 | 0 |
| 24 | 4 | 4 | 0 |
| 48 | 8 | 7 | 0 |
| 120 | 19 | 15 | 0 |
| 168 | 27 | 19 | 0 |
| 200 | 32 | 21 | 0 |

The results in Table 5 show that Comparative Examples C1 and C2 exhibited significant vertical displacement during the heat treatment. This vertical displacement is a measurement of creep. In contrast, the nanofilled composition (Example 1) exhibited no measureable vertical displacement throughout the duration of the tests. This result indicates that the nanofilled composition has very low creep or excellent creep resistance.

### Preparation of ION-2/NF-1 Masterbatch MB2 by Melt Extrusion

A ZSK-18 mm intermeshing, co-rotating twin-screw extruder (Coperion Corporation of Ramsey, N.J.) with 41 Length/Diameter (L/D) was used to make a an ION-2/NF-1 composite concentrate masterbatch using a melt extrusion process with water injection and removal. A conventional screw configuration was used containing a solid transport zone to convey pellets and clay powder from the first feed port, a melting section consisting of a combination of kneading blocks and several reverse pumping elements to create a seal to minimize water vapor escape, a melt conveying and liquid injection region, an intensive mixing section consisting of several combinations kneading block, gear mixer and reverse pumping elements to promote dispersion, distribution and polymer dissolution and water diffusion, one melt degassing and water removal zone and a melt pumping section. The melt was extruded through a die to form strands that were quenched in water at room temperature and cut into pellets. Polymer pellets and solid powders were metered into the extruder separately using loss in weight feeders (KTron Corp., Pitman, N.J.). Deionized (de-mineralized) water was injected into the extruder downstream of the melting zone using a positive displacement pump (Teledyne ISCO 500D, Lincoln, Nebr.). No attempt to exclude oxygen from the extruder was made. One vacuum vent zone was used to extract a portion of the water, volatile gases and entrapped air. Barrel temperatures, after the unheated feed barrel section, were set in a range from 160 to 185° C. depending on heat transfer and thermal requirements for melting, liquid injection, mixing, water removal and extrusion through the die. The throughput was fixed at 10 lb/hr and the screw rotational speed was 500 rpm. The deionized water injection flow rate was set to approximately 30 mL/minute. The extruded masterbatch pellets were then fed into the extruder for a second pass at a throughput of 10 lb/hr, a screw speed of 525 rpm, and a water injection flow rate of 16 ml/minute. A masterbatch with NF-1 silicate concentration of 25 weight % was produced. No organic surface modifiers were used on the NF-1 or added during the extrusion process.

### General Procedure for Preparing Ionomer Blends by Extrusion Melt Blending

A ZSK-18 mm intermeshing, co-rotating twin-screw extruder (Coperion Corp.) with 41 Length/Diameter (L/D) was used to melt and mix masterbatch MB2 described immediately above with ION-1 matrix polymer. A conventional screw configuration was used containing a solid transport zone to convey pellets from the first feed port, a melting section consisting of a combination of kneading blocks and one or more reverse pumping elements, a melt conveying region, a distributive mixing section consisting of several combinations of kneading block, gear mixer and reverse pumping elements, one melt degassing zone and a melt pumping section. Host (matrix) polymer and masterbatch pellets were metered into the extruder separately using two loss-in-weight feeders (KTron Corp.). No attempt to exclude oxygen from the extruder was made. For these samples, barrel temperatures were set in a range from 150 to 180° C. depending on heat transfer and thermal requirements for melting, mixing and extrusion through the die. The melt was then extruded through a die to form strands that were quenched in water at room temperature and cut into pellets. The throughput was fixed at 12 lb/hr and the screw rotational speed was 350 rpm. Extruded pellet samples were dried in conventional pellet drying equipment at 60 to 65° C. to reduce the moisture level below 1000 ppm. Pellet samples were packaged in metal lined, vacuum sealed bags. The compositions of the blends thus produced are summarized in Table 6. Similar blends comprising ION-3 and 5 or 10 weight % of nanofiller are prepared using a similar procedure by substituting ION-3 for ION-1.

TABLE 6

| | Comparative Example C3 | Example 2 | Example 3 |
|---|---|---|---|
| ION-2 (weight %) | 30 | 15 | 30 |
| NF-1 (weight %) | 0 | 5 | 10 |
| ION-1 (weight %) | 70 | 80 | 60 |

Four films of each composition in Table 6 were prepared using the procedure described for Comparative Example C1 above. The films were used to prepare glass/interlayer/glass laminates according to the general procedure described above. After lamination the encapsulant interlayer in each laminate was about 33 to 34 mils thick in a total laminate thickness of about 264 to 279 mils thick.

Solar Energy Transmittance Testing

The glass laminates were thoroughly cleaned using Windex® glass cleaner and lintless cloths to ensure that they were substantially free of dirt and other contaminants that might otherwise interfere with making valid optical measurements. The transmission spectrum of each laminate was then determined using a Varian Cary 5000 UV/VIS/NIR spectrophotometer (version 1.12) equipped with a DRA-2500 diffuse reflectance accessory, scanning from 2500 nm to 200 nm, with UV-VIS data interval of 1 nm and UV-VIS-NIR scan rate of 0.200 seconds/nm, utilizing full slit height and operating in double beam mode. The DRA-2500 is a 150 mm integrating sphere coated with Spectralon™. A total transmittance spectrum was obtained for each laminate and used to calculate Total Solar Energy Transmittance (τₛₑ) over the range of wavelengths from 1100 to 300 nm according to the method described in DIN EN 410. The results are summarized in Table 7. Solar energy transmittance is an indicator of the total solar energy that would be transmitted through the laminate to a photovoltaic cell.

TABLE 7

| Laminate | Solar Energy Transmittance (%) |
|---|---|
| Comparative Example C3 | 88.24 |
| Example 2 | 88.27 |
| Example 3 | 87.80 |

The data in Table 8 show that solar energy transmittance was not significantly affected by the inclusion of 5 to 10 weight % of nanofiller.

### Creep Test

The glass laminates were tested for creep performance according to the general procedure described above and the results as the average of eight measurements (four measurements of each laminate, two laminates of each interlayer) are summarized in Table 8.

TABLE 8
Vertical Displacement in mm

| | | | |
|---|---|---|---|
| Time (hours) | Comparative Example C3 | Example 2 | Example 3 |

T = 105° C.

| | | | |
|---|---|---|---|
| 2.5 | 0 | 0 | 0 |
| 8 | 1.7 | 0.4 | 0 |
| 24 | 4 | 1.7 | 0 |
| 48 | 8 | 2.7 | 0 |
| 120 | 18.6 | 4 | 0 |
| 144 | 23 | 4.4 | 0 |
| 200 | 33 | 5.6 | 0.2 |

T = 115° C.

| | | | |
|---|---|---|---|
| 2 | 0.7 | 0 | 0 |
| 6 | 2.3 | 0.6 | 0 |
| 24 | 9.5 | 2.5 | 0 |
| 48 | 20.4 | 4.1 | 0 |
| 120 | 58.9 | 8.0 | 0.7 |
| 168 | 76* | 9.9 | 0.8 |
| 200 | 76* | 10.9 | 0.9 |

*Maximum displacement possible in this test assembly

The results in Table 8 show that Comparative Example C3 exhibited significant creep during the thermal exposure. In contrast, the nanofilled compositions (Examples 2 and 3) exhibited superior creep resistance throughout the duration of the tests. Example 3, in which the ionomeric interlayer sheet contained 10 weight % of nanofiller, provided excellent creep resistance.

Heat deflection temperature (HDT) may be determined for the compositions at 264 psi (1.8 MPa) according to ASTM D648.

While certain of the preferred embodiments of this invention have been described and specifically exemplified above, it is not intended that the invention be limited to such embodiments. It is to be understood, moreover, that even though numerous characteristics and advantages of this invention have been set forth in the foregoing description, together with details of the structure and function of the invention, the disclosure is illustrative only, and changes may be made in detail, especially in matters of shape, size and arrangement of parts, within the principles of the invention to the full extent indicated by the broad general meaning of the terms in which the appended claims are expressed.

What is claimed is:

1. A solar cell module comprising a solar cell layer and a sheet comprising at least one layer of a nanofilled ionomer composition, wherein (a) the solar cell layer comprises a single solar cell or a plurality of electrically interconnected solar cells; (b) the solar cell layer has a light-receiving side and a non-light-receiving side; and (c) the nanofilled ionomer composition comprises
(1) an ionomer that is an ionic, neutralized derivative of a precursor α-olefin carboxylic acid copolymer, wherein about 10% to about 35% of the total content of the carboxylic acid groups present in the precursor α-olefin carboxylic acid copolymer is neutralized to form salts containing alkali metal cations, alkaline earth metal cations, transition metal cations, or combinations of two or more of these metal cations, and wherein the precursor α-olefin carboxylic acid copolymer comprises (i) copolymerized units of an α-olefin having 2 to 10 carbons and (ii) about 15 to about 25 weight %, based on the total weight of the precursor α-olefin carboxylic acid copolymer, of copolymerized units of an α,β-ethylenically unsaturated carboxylic acid having 3 to 8 carbons, wherein the ionomer has a melt flow rate (MFR) of about 0.1 g/10 min to about 60 g/10 min,
(2) one or more nanofillers; and optionally
(3) a second ionomer comprising a parent acid copolymer that comprises copolymerized units of ethylene and about 18 to about 30 weight % of copolymerized units of acrylic acid or methacrylic acid, based on the total weight of the parent acid copolymer, the acid copolymer having a melt flow rate (MFR) from about 200 to about 1000 g/10 min., wherein about 50% to about 70% of the carboxylic acid groups of the copolymer, based on the total carboxylic acid content of the parent acid copolymer as calculated for the non-neutralized parent acid copolymer, are neutralized to carboxylic acid salts comprising sodium cations, potassium cations or a combination thereof; and the second ionomer has a MFR from about 1 to about 20 g/10 min. wherein MFR is measured according to ASTM D1238 at 190° C. with a 2.16 kg load.

2. The solar cell module of claim 1 wherein the precursor α-olefin carboxylic acid copolymer comprises about 18 to about 25 weight % of copolymerized units of the α,β-ethylenically unsaturated carboxylic acid and wherein the precursor α-olefin carboxylic acid copolymer has a melt flow rate of about 100 g/10 min or less and the ionomer has a melt flow rate of about 30 g/10 min or less.

3. The solar cell module of claim 2 wherein the precursor α-olefin carboxylic acid copolymer comprises about 18 to about 23 weight % of copolymerized units of the α,β-ethylenically unsaturated carboxylic acid.

4. The solar cell module of claim 2 wherein the precursor α-olefin carboxylic acid copolymer has a melt flow rate of about 30 g/10 min or less and the ionomer has a melt flow rate of about 5 g/10 min or less.

5. The solar cell module of claim 2 wherein the-ionomer has a flexural modulus greater than about 40,000 psi (276 MPa), as determined in accordance with ASTM D638.

6. The solar cell module of claim 1 wherein the nanofiller is present at a level of about 3 to about 70 weight % based on the total weight of the nanofilled ionomer composition and comprises a nano-sized silica a nanoclay, or carbon nanofibers and has a particle size of about 0.9 to about 200 nm.

7. The solar cell module of claim 6 wherein the nano-sized silica comprises fumed silica, colloidal silica, fused silica, silicate, or mixtures of two or more thereof.

8. The solar cell module of claim 6 wherein the nanoclay comprises smectite, hectorite, fluorohectorite, montmorillonite, bentonite, beidelite, saponite, stevensite, sauconite, nontronite, illite, synthetic nanoclay, modified nanoclay, or mixtures of two or more thereof.

9. The solar cell module of claim 6 wherein the average aspect ratio of the nanofiller is about 30 to about 150.

10. The solar cell module of claim 6 wherein the nanofiller is a synthetic hectorite that is a Type 2 sodium magnesium silicate having a cation exchange capacity of about 60 meq/100 g, a platelet form, and a particle size of at least 50 nm in its largest dimension and about 1 nm thick.

11. The solar cell module of claim 1 wherein the sheet comprising the nanofilled ionomer composition is a monolayer that consists essentially of the nanofilled ionomer composition.

12. The solar cell module of claim 1 wherein the sheet comprising the nanofilled ionomer composition is a multilayer sheet having two or more sub-layers, and wherein at least one of the sub-layers consists essentially of the nanofilled ionomer composition.

13. The solar cell module of claim 12 wherein-each of the other sub-layers present in the multilayer sheet independently comprises a copolymer of an α-olefin and an α,β-ethylenically unsaturated carboxylic acid or ionomer thereof, poly(ethylene vinyl acetate), poly(vinyl acetal), polyurethane, polyvinylchloride, polyethylene, polyolefin block elastomer, silicone elastomer, epoxy resin, or combination of two or more thereof.

14. The solar cell module of claim 1 comprising a front encapsulant layer laminated to the light-receiving side of the solar cell layer and a back encapsulant layer laminated to the non-light-receiving side of the solar cell layer, wherein at least one of the front and back encapsulant layers comprises the sheet comprising the nanofilled ionomer composition.

15. The solar cell module of claim 14 wherein a layer comprising the nanofilled ionomer composition is directly laminated to the solar cell layer.

16. The solar cell module of claim 1 comprising a front encapsulant layer laminated to the light-receiving side of the solar cell layer and a back encapsulant layer laminated to the non-light-receiving side of the solar cell layer, wherein one of the front and back encapsulant layers is the sheet comprising the nanofilled ionomer composition and the other of the front and back encapsulant layers comprises a copolymer of an α-olefin and an α,β-ethylenically unsaturated carboxylic acid or an ionomer thereof, poly(ethylene vinyl acetate), poly(vinyl acetal), polyurethane, polyvinylchloride, polyethylene, polyolefin block elastomer, silicone elastomer, epoxy resin, or combinations thereof.

17. The solar cell module of claim 1 comprising in order of position (i) an incident layer wherein the incident layer is an outermost surface layer of the module and is positioned on the light-receiving side of the solar cell layer wherein the incident layer comprises a glass sheet, a polymeric sheet comprising polycarbonate, acrylic, polyacrylate, cyclic polyolefin, polystyrene, polyamide, polyester, fluoropolymer, or combinations of two or more thereof, or a polymeric film comprising polyester, polycarbonate, polyolefin, norbornene polymer, polystyrene, styrene-acrylate copolymer, acrylonitrile-styrene copolymes, polysulfone, polyamide, polyurethane, acrylic, cellulose acetate, cellophane, poly(vinyl chloride), fluoropolymer, or combination of two or more thereof; (ii) a front encapsulant layer laminated to the light-receiving side of the solar cell layer, (iii) the solar cell layer, (iv) a back encapsulant layer laminated to the non-light receiving side of the solar cell layer, and optionally (v) a backing layer wherein the incident layer is an outermost surface layer of the module and is positioned on the non-light receiving side of the solar cell layer, wherein at least one of the front and back encapsulant layers is the sheet comprising the nanofilled ionomer composition; and wherein the optional backing layer comprises a glass sheet, a polymeric sheet, a polymeric film, a metal sheet, or ceramic plate, and wherein the polymeric sheet comprises a polycarbonate, acrylic, polyacrylate, cyclic polyolefin, polystyrene, polyamide, polyester, fluoropolymer, or combination of two or more thereof; and the polymeric film comprises a polyester, polycarbonate, polyolefin, norbornene polymer, polystyrene, styrene-acrylate copolymer, acrylonitrile-styrene copolymer, polysulfone, polyamide, polyurethane, acrylic, cellulose acetate, cellophane, poly(vinyl chloride), fluoropolymer, or combination of two or more thereof.

18. The solar cell module of claim 1 wherein each of the front and back encapsulant layers comprises the nanofilled ionomer composition.

19. The solar cell module of claim 1 wherein the solar cells are wafer-based solar cells comprising crystalline silicon or multi-crystalline silicone based solar cells.

20. The solar cell module of claim 1 wherein the solar cells are thin film solar cells comprising amorphous silicon, microcrystalline silicon, cadmium telluride, copper indium selenide, copper indium/gallium diselenide, light absorbing dye, or organic semiconductor based solar cells.

21. The solar cell module of claim 1 comprising in order of position (i) an incident layer, (ii) a front encapsulant layer comprising the sheet comprising the nanofilled ionomer composition, and (iii) the solar cell layer, wherein the solar cell layer further comprises a substrate upon which the thin film solar cells are deposited and the substrate is positioned such that the substrate is an outermost surface of the module and is positioned on the non-light-receiving side of the solar cell layer.

22. The solar cell module of claim 1 comprising in order of position, (i) the solar cell layer, (ii) a back encapsulant layer comprising the sheet comprising the nanofilled ionomer composition, and (iii) a backing layer, wherein the solar cell layer further comprises a superstrate upon which the thin film solar cells are deposited and the superstrate is positioned such that the superstrate is an outermost surface of the module on the light-receiving side of the solar cell layer.

23. A process for preparing the solar cell module of claim 1 comprising: (i) providing an assembly comprising the solar cell layer and the sheet; and (ii) laminating the assembly to form the solar cell module, wherein the laminating step is conducted by subjecting the assembly to heat, optionally further comprising subjecting the assembly to vacuum or pressure.

24. The process of claim 23 wherein the nanofilled ionomer composition is prepared by
(1) mixing the second ionomer with water heated to a temperature from about 80 to about 90° C. to provide a heated aqueous ionomer dispersion;
(2) optionally cooling the aqueous ionomer dispersion to ambient temperature;
(3) mixing the aqueous ionomer dispersion with the nanofiller to provide an aqueous dispersion of ionomer and nanofiller;
(4) removing the water from the aqueous dispersion of ionomer and nanofiller to provide a mixture of water dispersable ionomer and nanofiller in solid form;
(5) melt blending the mixture of water dispersable ionomer and nanofiller with the first ionomer; or
wherein the nanofilled ionomer composition is prepared by
(a) combining the second ionomer, water and the nanofiller in a high-shear melt-mixing process in a piece of equipment to form a melted mixture;
(b) continuing the high-shear melt-mixing until the nanoparticles are sufficiently comminuted or dispersed;
(c) optionally, removing some or all of the water from the melted mixture;
(d) optionally, repeating the addition and removal of water from the melted mixture;
(e) adding the first ionomer to the melted mixture to form the nanofilled ionomer composition; and
(f) removing the nanofilled ionomer composition from the piece of equipment.
